(19) United States
(12) Patent Application Publication
(10) Pub. No.: US 2009/0127688 A1
(43) Pub. Date: May 21, 2009

(54) PACKAGE-ON-PACKAGE WITH IMPROVED JOINT RELIABILITY

(75) Inventors: Tae-Young LEE, Seoul (KR); Dong-Ha LEE, Chungcheongnam-do (KR); Cheol-Woo LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/173,161

(22) Filed: Jul. 15, 2008

(30) Foreign Application Priority Data
Nov. 16, 2007 (KR) 2007-00117443

(51) Int. Cl. H01L 23/31

(52) U.S. Cl. 257/686; 257/E23.172

(57) ABSTRACT

Provided is a package-on-package (POP) having an improved joint reliability. The POP includes a lower package, an upper package that is mounted on the lower package, and a plurality of joint members that electrically connect the lower package to the upper package. The lower package includes a lower substrate and a lower semiconductor chip mounted on a first surface of the lower substrate. The upper package includes an upper substrate and at least one upper semiconductor chip mounted on the upper substrate. The joint members are arranged between the lower package and the upper package. The lower package further includes a lower sealing member that is completely filled in a space between the upper substrate of the upper package and the lower substrate of the lower package to surround the joint members and protect the lower semiconductor chips.

### CROSS-REFERENCE TO RELATED PATENT APPLICATION

This application claims priority under 35 USC §119 to Korean Patent Application No. 10-2007-0117443, filed on Nov. 16, 2007 in the Korean Intellectual Property Office, the disclosure of which is incorporated herein in its entirety by reference.

### BACKGROUND

1. Technical Field

The present invention relates to a semiconductor package, and more particularly, to a package-on-package (POP) semiconductor package with improved joint reliability.

2. Description of the Related Art

As the size of electronic devices is reduced, a high integration density is realized by stacking a plurality of chips or stacking individual semiconductor packages in a single semiconductor package. Recently, a stack type semiconductor package has been introduced for mobile electronic equipment applications and the like. One such stack type semiconductor package is a package-on-package (POP) in which a logic package and a memory package are embedded into one package. Using POP technology, different types of semiconductor devices can be included in a single semiconductor package.

In a conventional POP, in order to realize a high integration density and a small mounting area, two packages are stacked and are electrically connected through solder balls. However, in the conventional POP, because the semiconductor packages are stacked through solder balls after fabricating individual semiconductor chips, a thickness of the solder balls is controlled depending on the molding thickness of the lower semiconductor package, and thus, an overall thickness of the semiconductor package is increased.

Also, when an upper package is stacked on a lower package at a high temperature, a warpage of the upper package or the lower package occurs, resulting in a poor contact at joining portions (joints) between the upper package and the lower package. Also, cracks can be generated in the solder balls after stacking. Thus, yield and reliability of the semiconductor package is reduced.

### SUMMARY

To address the above and/or other problems, the present invention provides a POP that can prevent poor contact at joint portions and cracks in the solder balls.

The POP according to some embodiments of the present invention comprises a lower package, an upper package overlying the lower package and a plurality of joint members electrically connecting the lower and upper packages. The lower package comprises a lower substrate and a lower semiconductor chip mounted on a first surface of the lower substrate. The upper package comprises an upper substrate and at least one upper semiconductor chip mounted on a first surface of the upper substrate. The plurality of joint members is arranged between the lower package and the upper package. The lower package further comprises a sealing member disposed between the upper substrate of the upper package and the lower substrate of the lower package so as to substantially surround the joint members and protect the lower semiconductor chip.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a package-on-package (POP) according to an embodiment of the present invention;

FIG. 2 is a cross-sectional view of a POP according to another embodiment of the present invention;

FIGS. 3A through 3G are cross-sectional views illustrating a method of manufacturing a POP according to an embodiment of the present invention;

FIGS. 4A through 4H are cross-sectional views illustrating a method of manufacturing a POP according to another embodiment of the present invention; and

FIGS. 5A through 5C are cross-sectional views illustrating a method of manufacturing a POP according to another embodiment of the present invention.

### DETAILED DESCRIPTION OF EXAMPLE EMBODIMENTS

The present invention will now be described more fully with reference to the accompanying drawings, in which exemplary embodiments of the invention are shown. The invention may, however, be embodied in many different forms and should not be construed as being limited to the embodiments set forth herein. Instead, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

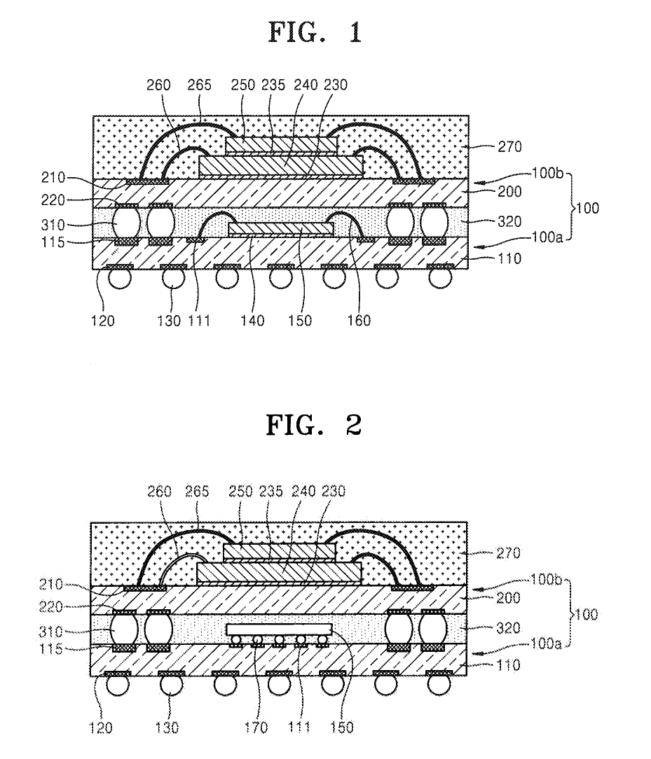

FIG. 1 is a cross-sectional view of a package-on-package (POP) 100 according to an embodiment of the present invention. Referring to FIG. 1, the POP 100 includes a lower package 100a and an upper package 100b stacked on the lower package 100a. The lower package 100a includes a lower substrate 110 and a lower semiconductor chip 150 mounted on the lower substrate 110. First connection pads 111 and second connection pads 115 are arranged on a first surface of the lower substrate 110, and third connection pads 120 are arranged on a second surface of the lower substrate 110. The first surface is opposite the second surface. The lower substrate 110 can include a printed circuit board (PCB). The lower semiconductor chip 150 is mounted on the first surface of the lower substrate 110 using an adhesive 140. The lower semiconductor chip 150 is electrically connected to the first connection pads 111 through bonding wires 160. The lower semiconductor chip 150 can include a logic chip.

The lower substrate 110 can further include external connection terminals 130 arranged on the third connection pads 120. The lower substrate 110 can further include circuit wires (not shown) that are arranged in the lower substrate 110 to electrically connect the first connection pads 111 and the second connection pads 115 to the third connection pads 120.

The upper package 100b includes an upper substrate 200 and at least one of upper semiconductor chips 240 and 250 mounted on the upper substrate 200. The upper substrate 200 includes first connection pads 210 arranged on a first surface thereof and second connection pads 220 arranged on a second surface thereof. The first surface is opposite the second surface. The upper substrate 200 can further include circuit wires (not shown) that are arranged in the upper substrate 200 to electrically connect the first connection pads 210 and the second connection pads 220. The upper substrate 200 can include a PCB.

The first upper semiconductor chip 240 is mounted on the first surface of the upper substrate 200 using, for example, an adhesive 230 and the second upper semiconductor chip 250 is mounted on the first upper semiconductor chip 240 using, for example, an adhesive 235. The first upper semiconductor chip 240 and the second upper semiconductor chip 250 are electrically connected to the first connection pads 210 of the upper substrate 200 through bonding wires 260 and 265. However, one skilled in the art will appreciate that other known interconnection methods can be used to connect the first upper semiconductor chip 240 and the second upper semiconductor chip 250 with the first connection pads 210 of the upper substrate 200. The first and second upper semiconductor chips 240 and 250 each can include one or more memory chips. An upper sealing member 270 is formed on the upper substrate 200 to cover the first and second upper semiconductor chips 240 and 250 and the wires 260 and 265. The upper sealing member 270 can include an epoxy molding compound.

The POP 100 can further include a joint member 310 for joining the lower package 100a and the upper package 100b. The joint member 310 electrically connects the second connection pads 115 of the lower package 100a to the second connection pads 220 of the upper package 100b. The joint member 310 can include solder balls. A lower sealing member 320 is disposed in a space between the lower substrate 110 and the upper substrate 200 to cover the joint member 310, the lower semiconductor chip 150, and the bonding wires 160. The lower sealing member 320 can include an epoxy molding compound. The lower sealing member 320 may be filled in the space between an upper surface of the lower substrate 110 and a lower surface of the upper substrate 200, and thus, supports the joint member 310 and also protects the lower semiconductor chip 150 and the bonding wires 160.

In other words, the lower sealing member 320 may be disposed between the upper substrate 200 of the upper package 100b and the lower substrate 110 of the lower package 100a so as to substantially surround the joint members 310 and protect the lower semiconductor chip 150. In one embodiment, the lower sealing member 320 may substantially completely fill the space between the upper substrate 200 of the upper package 100b and the lower substrate 110 of the lower package 100a.

FIG. 2 is a cross-sectional view of a POP 100 according to another embodiment of the present invention. The POP 100 of FIG. 2 has a different lower package 100a from the POP 100 of FIG. 1. A semiconductor chip 150 is mounted on a lower substrate 110, and is electrically connected to first connection pads 111 of the lower substrate 110 through solder balls 170. In the upper packages 100b of the POPs 100 of FIGS. 1 and 2, upper semiconductor chips 240 and 250 can also be electrically connected to first connection pads 210 of the upper substrate 200 through solder balls instead of the bonding wires 260 and 265, similar to the lower package 100a of FIG. 2.

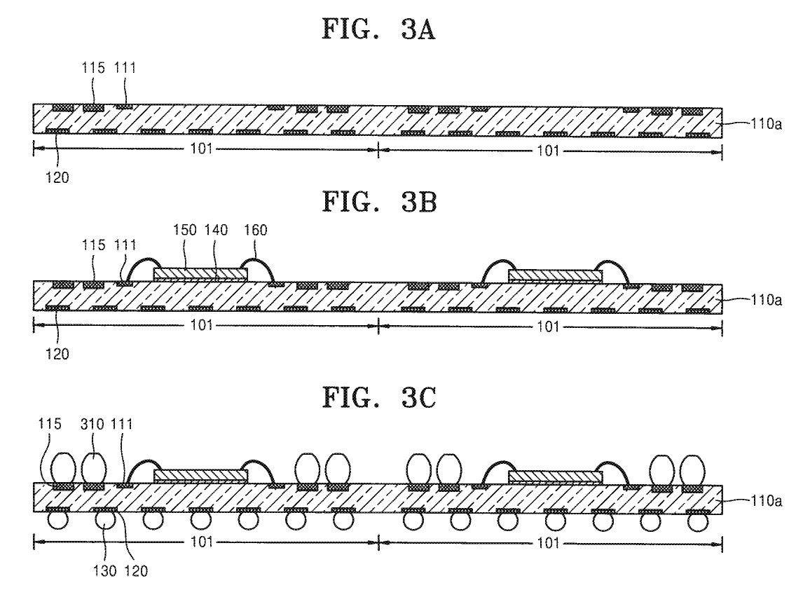

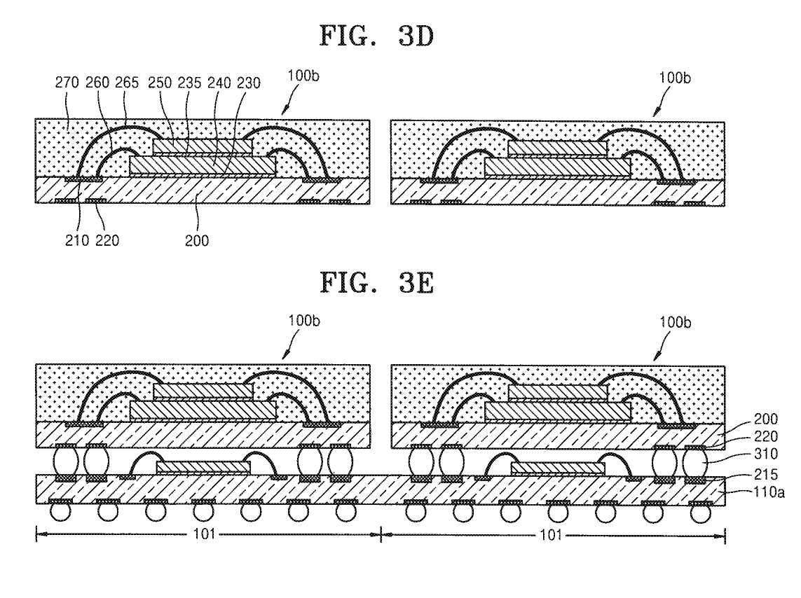

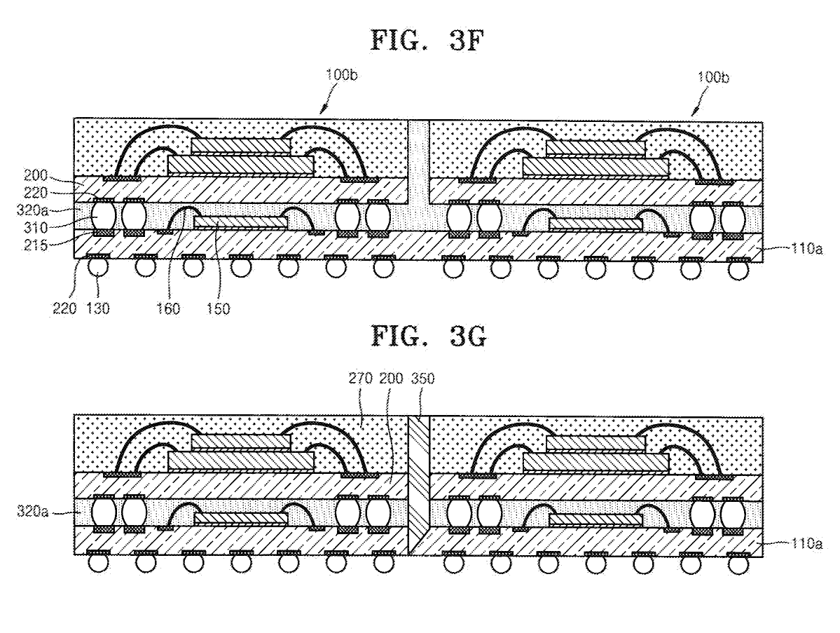

FIGS. 3A through 3G are cross-sectional views illustrating a method of manufacturing a POP according to an embodiment of the present invention. Referring to FIG. 3A, a lower mother substrate 110a for a lower semiconductor package 100a (refer to FIG. 1) is provided. The lower mother substrate 110a can include a PCB. The lower mother substrate 110a includes a plurality of lower unit substrate regions 101. Each of the lower unit substrate regions 101 will be the lower substrate 110 of FIG. 1 when the lower mother substrate 110a is cut in a subsequent process. First connection pads 111 and second connection pads 115 are arranged on a first surface of each of the lower unit substrate regions 101. The first connection pads 111 will be connected to a lower semiconductor chip 150 (refer to FIG. 1) which will be mounted in a subsequent process and the second connection pads 115 will be connected to an upper semiconductor package 100b (refer to FIG. 1) which is stacked in a subsequent process. Third connection pads 120 are arranged on a second surface of each of the lower unit substrate regions 101.

Referring to FIG. 3B, lower semiconductor chips 150 are stacked on each of the lower unit substrate regions 101 of the lower mother substrate 110a using an adhesive 140. The lower semiconductor chips 150 can include logic chips. The lower semiconductor chips 150 are electrically connected to the first connection pads 111 through bonding wires 160 by performing a wire bonding process. Alternatively, as in FIG. 2, the lower semiconductor chips 150 can be bonded to the first connection pads 111 of each of the lower unit substrate regions 101 of the lower mother substrate 110a through solder balls 170.

Referring to FIG. 3C, external connection terminals 130 are attached to the third connection pads 120 of the lower unit substrate regions 101, and joint members 310 are attached to the second connection pads 115. The external connection terminals 130 can include solder balls. The joint members 310 can also include solder balls.

Referring to FIG. 3D, individual upper packages 100b are provided. Each of the upper packages 100b includes an upper substrate 200. First connection pads 210 are arranged on a first surface of the upper substrate 200, and second connection pads 220 are arranged on a second surface of the upper substrate 200. Upper semiconductor chips 240 and 250 are stacked on the first surface of the upper substrate 200 using adhesives 230 and 235. The upper semiconductor chips 240 and 250 are electrically connected to the first connection pads 210 of the upper substrate 200 through bonding wires 260 and 265 by performing a wire bonding process. An upper sealing member 270 is formed on the upper substrate 200 to protect the upper semiconductor chips 240 and 250 and the bonding wires 260 and 265.

Referring to FIG. 3E, the upper packages 100b are respectively stacked on each of the lower unit substrate regions 101 of the lower mother substrate 110a. The upper packages 100b are mounted on the joint members 310, and thus, the second connection pads 220 of the upper substrate 200 are electrically connected to second connection pads 215 of each of the lower unit substrate regions 101 of the lower mother substrate 110a through the joint members 310.

Referring to FIG. 3F, a lower mother sealing member 320a is formed by performing a molding process so as to fill a space between the upper substrate 200 and the lower mother substrate 110a and spaces between the upper packages 100b. The lower mother sealing member 320a fixes the joint members 310 and protects lower semiconductor chips 150 and the bonding wires 160. The lower mother sealing member 320a will be the lower sealing member 320 of the POP 100 of FIG. 1 after a subsequent cutting process.

Referring to FIG. 3G, the POP 100 of FIG. 1 is manufactured by cutting the lower mother substrate 110a and the lower mother sealing member 320a by performing a sawing process using a blade 350 or a laser.

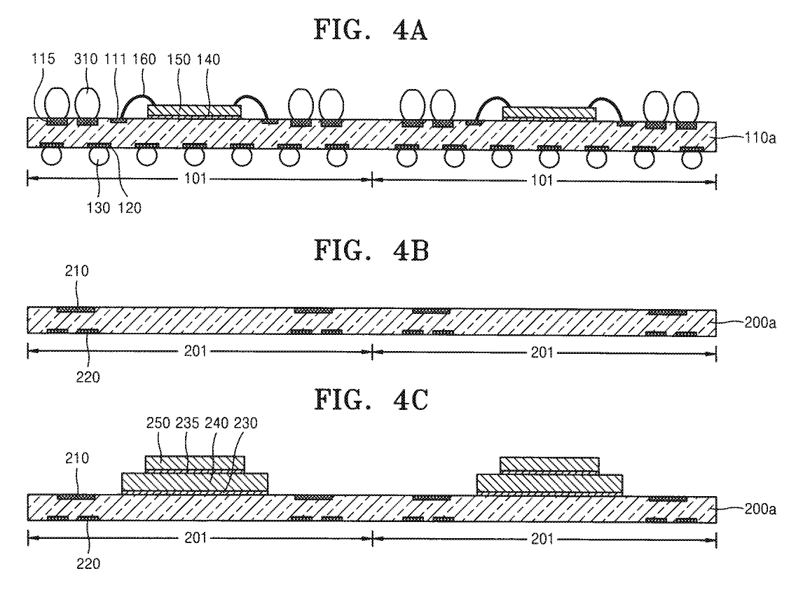

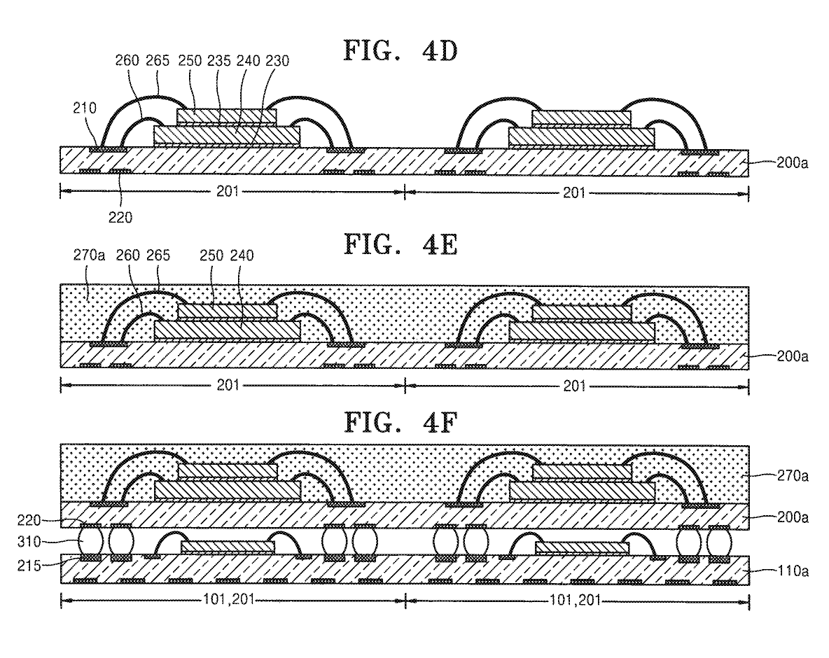

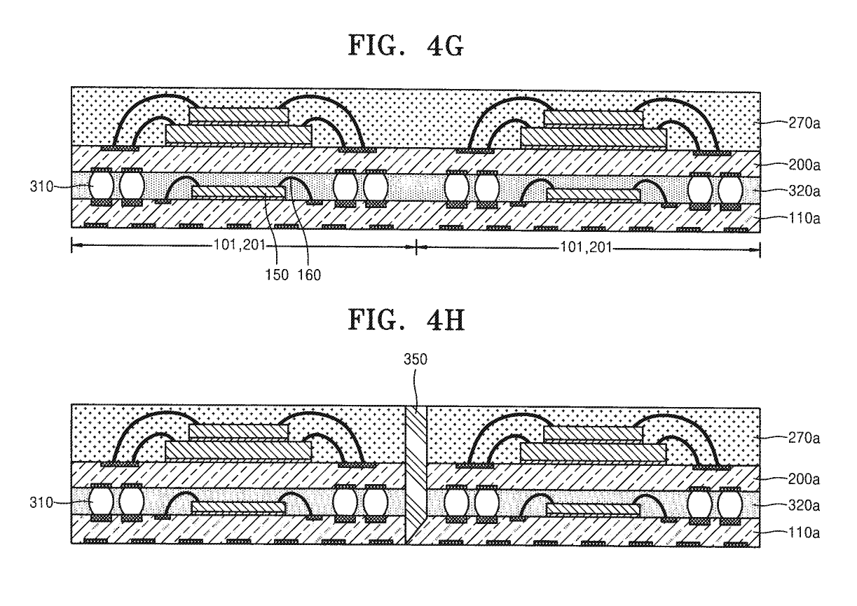

FIGS. 4A through 4H are cross-sectional views illustrating a method of manufacturing a POP according to another embodiment of the present invention. Referring to FIG. 4A, as in FIGS. 3A through 3C, a lower package is formed on a lower mother substrate 110a. The lower mother substrate 110a can include a PCB. Lower semiconductor chips 150 are mounted on a first surface of each of lower unit substrate regions 101 of the lower mother substrate 110a using an adhesive 140, and lower semiconductor chips 150 are connected to first connection pads 111 arranged on the first surface of each of the lower unit substrate regions 101 through bonding wires 160 by performing a wire bonding process. Alternatively, as in FIG. 2, the lower semiconductor chips 150 can be bonded to the first connection pads 111 of each of the lower unit substrate regions 101 of the lower mother substrate 110a through solder balls 170. Joint members 310 are attached to second connection pads 115 arranged on the first surface of each of the lower unit substrate regions 101, and external connection terminals 130 are attached to third connection pads 120 arranged on a second surface of each of the lower unit substrate regions 101.

Referring to FIG. 4B, an upper mother substrate 200a is provided. The upper mother substrate 200a includes a plurality of upper unit substrate regions 201. Each of the upper unit substrate regions 201 will be an upper substrate 200 of FIG. 1 when the upper mother substrate 200a is cut in a subsequent process. First connection pads 210 are arranged on a first surface of each of the upper unit substrate regions 201 and second connection pads 220 are arranged on a second surface of each of the upper unit substrate regions 201. The upper mother substrate 200a can include a PCB.

Referring to FIG. 4C, upper semiconductor chips 240 and 250 are respectively mounted on each of the upper unit substrate regions 201 of the upper mother substrate 200a using adhesives 230 and 235. The upper semiconductor chips 240 and 250 can include memory chips.

Referring to FIG. 4D, the first connection pads 210 of the upper unit substrate regions 201 are electrically connected to the upper semiconductor chips 240 and 250 through bonding wires 260 and 265 by performing a wire bonding process.

Referring to FIG. 4E, an upper mother sealing member 270a is formed on the upper mother substrate 200a to cover the upper semiconductor chips 240 and 250 and the bonding wires 260 and 265 formed on each of the upper unit substrate regions 201. The upper mother sealing member 270a will be the upper sealing member 270 of FIG. 1 after a subsequent cutting process.

Referring to FIG. 4F, the upper mother substrate 200a is stacked on the lower mother substrate 110a so that each of the lower unit substrate regions 101 of the lower mother substrate 110a can correspond to each of the upper unit substrate regions 201 of the upper mother substrate 200a. The second connection pads 220 of each of the upper unit substrate regions 201 of the upper mother substrate 200a are electrically connected to second connection pads 215 of each of the lower unit substrate regions 101 of the lower mother substrate 110a through the joint members 310.

Referring to FIG. 4G, a lower mother sealing member 320a is formed in a space between the upper mother substrate 200a and the lower mother substrate 110a. The lower mother sealing member 320a not only fixes the joint members 310 but also protects the lower semiconductor chips 150 and the bonding wires 160. The lower mother sealing member 320a will be the lower sealing member 320 of FIG. 1 after a subsequent cutting process.

Referring to FIG. 4H, the POP 100 of FIG. 1 is manufactured by cutting the lower mother substrate 110a, the lower mother sealing member 320a, the upper mother substrate 200a, and the upper mother sealing member 270a by performing a sawing process using a blade 350 or a laser.

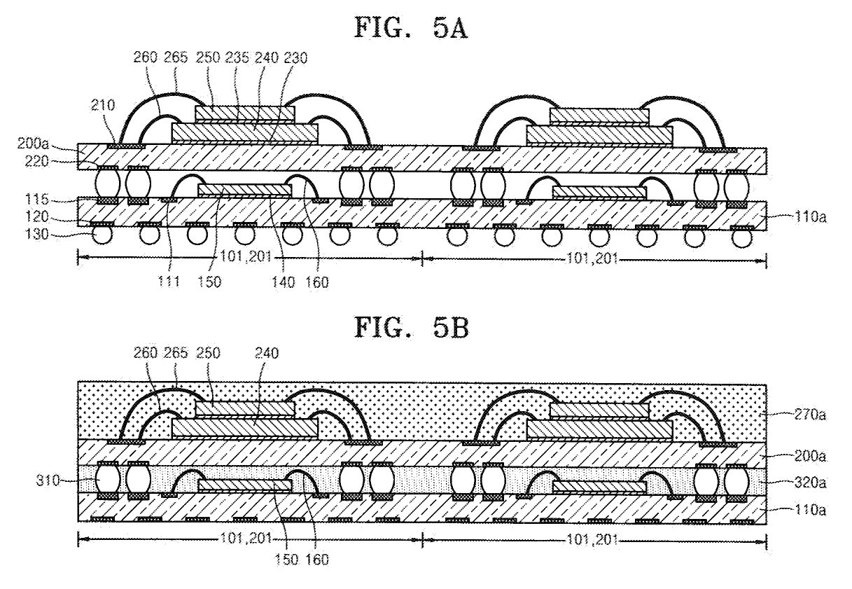

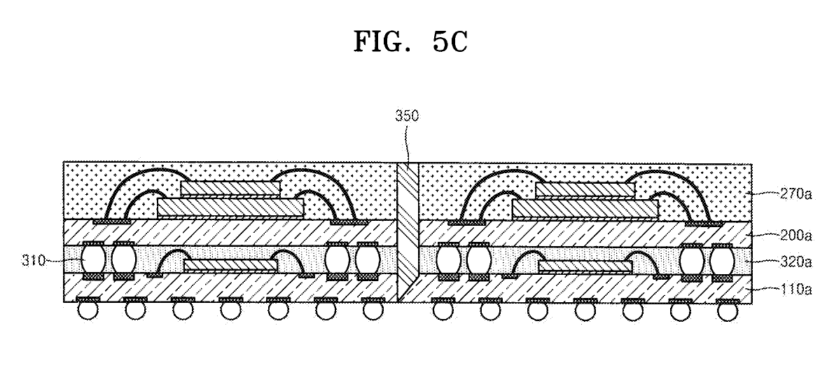

FIGS. 5A through 5C are cross-sectional views illustrating a method of manufacturing a POP according to another embodiment of the present invention. Referring to FIG. 5A, as in FIGS. 3A through 3C, a lower package is formed on a lower mother substrate 110a. The lower mother substrate 110a can include a PCB. Lower semiconductor chips 150 are mounted on a first surface of each of lower unit substrate regions 101 of the lower mother substrate 110a using an adhesive 140, and the lower semiconductor chips 150 are connected to first connection pads 111 arranged on the first surface of each of the lower unit substrate regions 101 through bonding wires 160 by performing a wire bonding process. Alternatively, as in FIG. 2, the lower semiconductor chips 150 can be bonded to the first connection pads 111 of each of the lower unit substrate regions 101 of the lower mother substrate 110a through solder balls 170. Joint members 310 are attached to second connection pads 115 arranged on the first surface of each of the lower unit substrate regions 101, and external connection terminals 130 are attached to third connection pads 120 arranged on a second surface of each of the lower unit substrate regions 101.

Next, as in FIGS. 4B through 4D, upper semiconductor chips 240 and 250 are respectively mounted on each of upper unit substrate regions 201 of an upper mother substrate 200a using adhesives 230 and 235. The first connection pads 210 of the upper unit substrate regions 201 are electrically connected to the upper semiconductor chips 240 and 250 through bonding wires 260 and 265 by performing a wire bonding process.

The upper mother substrate 200a is stacked on the lower mother substrate 110a so that each of the lower unit substrate regions 101 of the lower mother substrate 110a can correspond to each of the upper unit substrate regions 201 of the upper mother substrate 200a. The second connection pads 220 of each of the upper unit substrate regions 201 of the upper mother substrate 200a are electrically connected to the second connection pads 115 of each of the lower unit substrate regions 101 of the lower mother substrate 110a through the joint members 310.

Referring to FIG. 5B, a lower mother sealing member 320a is formed in a space between the upper mother substrate 200a and the lower mother substrate 110a and un upper mother sealing member 270a is formed on the upper mother substrate 200a by performing a single molding process. The lower mother sealing member 320a not only fixes the joint members 310 but also protects the lower semiconductor chip 150 and the bonding wires 160. The upper mother sealing member 270a protects the upper semiconductor chips 240 and 250 and the bonding wires 260 and 265. The lower mother sealing member 320a will be the lower sealing member 320 of FIG. 1, and the upper mother sealing member 270a will be the upper sealing member 270 after a subsequent cutting process.

Referring to FIG. 5C, the POP 100 of FIG. 1 is manufactured by cutting the lower mother substrate 110a, the lower mother sealing member 320a, the upper mother substrate 200a, and the upper mother sealing member 270a by performing a sawing process using a blade 350 or a laser.

In a POP according to an embodiment of the present invention, after stacking an upper package on a lower package through solder balls, the semiconductor chips and the solder balls are simultaneously molded by performing a molding process. Thus, the generation of cracks and poor contact at joint portions between the upper package and the lower package, which are caused due to warpage of the upper package or the lower package, can be minimized. Thus, product yield and reliability can be increased. Also, since the lower package is formed by performing a molding process after forming the solder balls, the size of the solder balls is independent of the molding thickness of the lower package, and thus, an overall thickness of the package can be reduced resulting in the reduction of the total dimensions, thereby enabling an increase in the integration density.

The POP according to some embodiments of the present invention comprises a lower package, an upper package mounted on the lower package and a plurality of joint members electrically connecting the lower and upper packages. The lower package comprises a lower substrate and a lower semiconductor chip mounted on a first surface of the lower substrate. The upper package comprises an upper substrate and at least one upper semiconductor chip mounted on a first surface of the upper substrate. The plurality of joint members is arranged between the lower package and the upper package. The lower package further comprises a sealing member that is completely filled in a space between the upper substrate of the upper package and the lower substrate of the lower package so as to substantially surround the joint members and protect the lower semiconductor chip.

The joint members may comprise solder balls and the lower sealing member may comprise an epoxy molding compound. The lower semiconductor chip may comprise a logic chip and the at least one upper semiconductor chip may comprise a memory chip.

The lower substrate may comprise a plurality of first connection pads arranged on the first surface of the lower substrate and a plurality of second connection pads arranged on the first surface of the lower substrate. The lower semiconductor chip may be electrically connected to the first connection pads through bonding wires or solder balls.

The upper substrate may comprise: a plurality of first connection pads arranged on the first surface of the upper substrate; and a plurality of second connection pads arranged on a second surface of the upper substrate. The at least one of the upper semiconductor chips is electrically connected to the first connection pads of the upper substrate through the bonding wires. The second connection pads of the upper substrate and the second connection pads of the lower substrate may be electrically connected through the joint members.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A package-on-package (POP) comprising:
a lower package including a lower substrate and a lower semiconductor chip mounted on a first surface of the lower substrate;
an upper package overlying the lower package, the upper package comprising an upper substrate and at least one upper semiconductor chip mounted on a first surface of the upper substrate;
a plurality of joint members disposed between the lower package and the upper package so as to electrically connect the lower package to the upper package; and
a lower sealing member disposed between the upper substrate of the upper package and the lower substrate of the lower package so as to substantially surround the joint members and protect the lower semiconductor chip.

2. The POP of claim 1, wherein the joint members comprise solder balls.

3. The POP of claim 1, wherein the lower sealing member comprises an epoxy molding compound.

4. The POP of claim 1, wherein the lower substrate comprises:
a plurality of first connection pads arranged on the first surface of the lower substrate; and
a plurality of second connection pads arranged on the first surface of the lower substrate,
wherein the lower semiconductor chips are electrically connected to the first connection pads.

5. The POP of claim 4, wherein the lower semiconductor chips are electrically connected to the first connection pads through bonding wires.

6. The POP of claim 4, wherein the lower semiconductor chips are electrically connected to the first connection pads through solder balls.

7. The POP of claim 4, wherein the upper substrate comprises:
a plurality of first connection pads arranged on the first surface of the upper substrate; and
a plurality of second connection pads arranged on a second surface of the upper substrate, the second surface opposite the first surface,
wherein at least one of the upper semiconductor chips is electrically connected to the first connection pads of the upper substrate.

8. The POP of claim 7, wherein the at least one of the upper semiconductor chips is connected to the first connection pads of the upper substrate through bonding wires.

9. The POP of claim 8, wherein the upper package further comprises an upper sealing member formed on the upper substrate to cover the at least one of the upper semiconductor chips and the bonding wires.

10. The POP of claim 9, wherein the upper sealing member comprises the same material as the lower sealing member.

11. The POP of claim 7, wherein the second connection pads of the upper substrate and the second connection pads of the lower substrate are electrically connected through the joint members.

12. The POP of claim 1, wherein the lower substrate comprises a printed circuit board (PCB).

13. The POP of claim 1, wherein the upper substrate comprises a PCB.

14. The POP of claim 1, wherein the lower semiconductor chip comprises a logic chip.

15. The POP of claim 1, wherein the at least one upper semiconductor chip comprises a memory chip.

16. The POP of claim 1, wherein the lower sealing member substantially completely fills the space between the upper substrate of the upper package and the lower substrate of the lower package.
